(19) United States
(12) Patent Application Publication
(10) Pub. No.: US 2012/0043633 A1
(43) Pub. Date: Feb. 23, 2012

(54) RADIATION DETECTOR

(76) Inventors: Junichi Suzuki, Kyoto-Fu (JP); Kenji Sato, Shiga-ken (JP); Hidetoshi Kishimoto, Kyoto-fu (JP)

(21) Appl. No.: 13/265,889

(22) PCT Filed: Apr. 30, 2009
(86) PCT No.: PCT/JP2009/001958

§ 371 Date: Oct. 24, 2011

(51) Int. Cl. H01L 31/115

(52) U.S. Cl. 257/429; 257/E31.086

(57) ABSTRACT

According to a radiation detector of this invention, a common electrode for bias voltage application and a lead wire for bias voltage supply are connected through a conductive plate as a planarly formed plate interposed therebetween. Since the conductive plate is connected instead of connecting the lead wire directly onto the common electrode, it can prevent damage to a radiation sensitive semiconductor and avoid performance degradation. Since the conductive plate is formed planarly, even if a conductive paste with high resistance is used, connection resistance can be lowered to be comparable to the use of silver paste. That is, the range of selection of the conductive paste is broadened. Also, connection can be made without using an insulating seat and performance degradation can be avoided. As a result, performance degradation can be avoided, without using an insulating seat.

### TECHNICAL FIELD

This invention relates to radiation detectors having a radiation sensitive semiconductor for generating electric charges upon incidence of radiation, for use in the medical, industrial, nuclear and other fields.

### BACKGROUND ART

Conventionally, radiation (e.g. X-ray) detectors of this type include an “indirect conversion type” detector which once generates light upon incidence of radiation (e.g. X-rays) and generates electric charges from the light, thus detecting the radiation by converting the radiation indirectly into the electric charges, and a “direct conversion type” detector which generates electric charges upon incidence of radiation, thus detecting the radiation by converting the radiation directly into the electric charges. The electric charges are generated by a radiation sensitive semiconductor.

As shown in FIG. 8, a direct conversion type radiation detector has an active matrix substrate 51, a radiation sensitive semiconductor 52 for generating electric charges upon incidence of radiation, and a common electrode 53 for bias voltage application. The active matrix substrate 51 has a plurality of collecting electrodes (not shown) formed on a radiation incidence surface thereof, with an electric circuit (not shown) arranged for storing and reading electric charges collected by the respective collecting electrodes. The respective collecting electrodes are set in a two-dimensional matrix arrangement inside a radiation detection effective area SA.

The semiconductor 52 is laid on the incidence surfaces of the collecting electrodes formed on the active matrix substrate 51, and the common electrode 53 is formed and laid planarly on the incidence surface of the semiconductor 52. A lead wire 54 for bias voltage supply is connected to the incidence surface of the common electrode 53.

In time of radiation detection by the radiation detector, a bias voltage from a bias voltage source (not shown) is applied to the common electrode 53 for bias voltage application via the lead wire 54 for bias voltage supply. With the bias voltage applied, electric charges are generated by the radiation sensitive semiconductor 52 upon incidence of the radiation. The generated electric charges are first collected by the collecting electrodes. The electric charges collected by the collecting electrodes are fetched as radiation detection signals from the respective collecting electrodes by the storing and reading electric circuit including capacitors, switching elements, electric wires and so on.

Each of the collecting electrodes in the two-dimensional matrix arrangement corresponds to an electrode (pixel electrode) corresponding to each pixel in a radiographic image. By fetching radiation detection signals, it becomes possible to create a radiographic image according to a two-dimensional intensity distribution of the radiation projected to the radiation detection effective area SA.

However, the conventional radiation detector shown in FIG. 8 has a problem of performance degradation resulting from the lead wire 54 being connected to the common electrode 53. That is, since a hard metal wire such as copper wire is used for the lead wire 54 for bias voltage supply, damage occurs to the radiation sensitive semiconductor 52 when the lead wire 54 is connected to the common electrode 53, thereby causing performance degradation such as a voltage resisting defect.

Particularly where the semiconductor 52 is amorphous selenium or a non-selenic polycrystalline semiconductor such as CdTe, CdZnTe, PbI₂, HgI₂ or TlBr, the radiation sensitive semiconductor 52 of large area and thickness may easily be formed by vacuum deposition. However, such amorphous selenium and non-selenic polycrystalline semiconductor are relatively soft and vulnerable to damage.

Amorphous selenium has a glass transition point around 40° C., a temperature above this will promote crystallization of a film of amorphous selenium, further lower the resistance of the film, and create a possibility of electric discharge caused by application of a bias voltage. Therefore, a method of connecting and fixing the lead wire 54 directly to the common electrode 53 at room temperature using a conductive paste is adopted, but this also has problems.

(1) For example, silver paste having silver as a main component is used as the conductive paste. Silver has a high rate of diffusion to amorphous selenium, and therefore lowers the electrical resistance of amorphous selenium, thereby tending to produce penetration discharge from the film of amorphous selenium by application of the bias voltage. Further, as noted above, (2) when connecting the lead wire 54 to the common electrode 53, damage can easily be done to the amorphous selenium forming the semiconductor 52.

Therefore, a method in which the conductive paste is replaced with a carbon-based paste or nickel-based paste is conceivable. However, with these pastes, (3) connection resistance becomes large compared with silver paste. Moreover, this cannot eliminate the problem (2) that damage can easily be done to the amorphous selenium forming the semiconductor 52 when similarly connecting the lead wire 54 to the common electrode 53.

In order to avoid the performance degradation resulting from the lead wire 54 being connecting to the common electrode 53, Inventors have proposed an invention as shown in FIG. 9 (see Patent Document 1, for example). As shown in FIG. 9 (corresponding to FIG. 2 of Patent Document 1), an insulating seat 55 is disposed on the incidence surface of the semiconductor 52 outside the radiation detection effective area SA. A common electrode 53 is formed to cover at least part of the seat 55, and a lead wire 54 is connected to a portion of the incidence surface of the common electrode 53 located on the seat 55.

With such seat 55 disposed, the seat 55 can reduce a shock occurring when the lead wire 54 is connected to the common electrode 53. This consequently prevents damage to the radiation sensitive semiconductor that leads to a voltage resisting defect, and avoids performance degradation such as voltage resisting defect. The seat 55 is disposed outside the radiation detection effective area SA, thereby preventing impairment of the radiation detecting function. Further, the use of silver paste enables a connection at low resistance.

In addition, Inventors have proposed an invention as shown in FIG. 10 (see Patent Document 2, for example) which is a further improvement on Patent Document 1 noted above. As shown in FIG. 10 (corresponding to FIG. 2 of Patent Document 2), a first common electrode 53a is formed planarly in direct contact with an incidence surface of a semiconductor 52, and an insulating seat 55 is disposed on an incidence surface of the first common electrode 53a to cover part of the first common electrode 53a. A second common electrode 53b is formed on an incidence side of the seat 55 to cover at least part of the seat 55, and the second common electrode 53b is connected to the first common electrode 53a. In this case also, impairment of the radiation detecting function is prevented by providing the seat, and the use of silver paste enables a connection at low resistance.

[Patent Document 1]

Unexamined Patent Publication No. 2005-86059 (pages 1, 2, 4 to 12, FIGS. 1, 2, 6 to 9)

[Patent Document 2]

International Publication No. WO 2008-143049

### DISCLOSURE OF THE INVENTION

### Problems to be Solved by the Invention

However, there are problems also when the insulating seat is provided as in Patent Documents 1 and 2 noted above. That is, (4) the film of amorphous selenium crystallizes by the components of the resin forming the seat, which generates dark current. Further, (5) a vapor deposition apparatus will be contaminated by the components of the resin forming the seat. With the problem (5), when the common electrode is formed by vapor deposition especially after forming the seat, the vapor deposition apparatus will be contaminated when forming the common electrode.

This invention has been made having regard to the state of the art noted above, and its object is to provide a radiation detector which can avoid performance degradation without using an insulating seat.

### Means for Solving the Problem

To fulfill the above object, this invention provides the following construction.

A radiation detector of this invention is a radiation detector for detecting radiation, comprising a radiation sensitive semiconductor for generating electric charges upon incidence of the radiation; a common electrode for bias voltage application formed planarly on an incidence surface of the semiconductor; a lead wire for bias voltage supply; and a conductive plate formed planarly; wherein the common electrode and the lead wire are connected through the plate interposed therebetween and the plate and the common electrode are connected by a conductive paste.

According to the radiation detector of this invention, the common electrode for bias voltage application and the lead wire for bias voltage supply are connected through the planarly formed conductive plate interposed therebetween. Since the planarly formed conductive plate is connected instead of connecting the lead wire directly onto the common electrode, it can prevent damage to the radiation sensitive semiconductor and avoid performance degradation. Since the plate is formed planarly, even if a conductive paste with high resistance is used, connection resistance can be lowered to be comparable to the use of silver paste. That is, the range of selection of the conductive paste is broadened. Also, connection can be made without using an insulating seat and performance degradation can be avoided. As a result, performance degradation can be avoided, without using an insulating seat.

In the above radiation detector of this invention, the plate and the common electrode is connected by a conductive paste, which can prevent damage to the radiation sensitive semiconductor and can lower connection resistance as noted above. Further, the plate and the common electrode is connected by a conductive tape, or the plate and the common electrode is connected by a conductive tape and a conductive paste formed thereon. Although resistivity may become high with the conductive tape compared with the conductive paste, resistance can be lowered since the conductive paste is formed on the conductive tape to be used in combination.

Further, the plate may have a through-hole accessible to the conductive paste. With the plate having such through-hole, the conductive paste enters the through-hole when the plate and common electrode are connected by the conductive paste. This increases mechanical strength, and can further lower the connection resistance. It is preferable that the conductive paste contains carbon or nickel. When the conductive paste is silver paste, although connection resistance is low, diffusion to the semiconductor represented by amorphous selenium is large, which will lower even the resistance of the semiconductor, causing penetration discharge of the semiconductor by application of a bias voltage. When the conductive paste is a carbon-based paste or nickel-based paste containing carbon or nickel, diffusion to the semiconductor is small compared with the silver paste, and hardly causes penetration discharge of the semiconductor. When the conductive paste is a carbon-based paste or nickel-based paste containing carbon or nickel, although connection resistance becomes high, since the plate is formed planarly, connection resistance can be lowered to a level similar to the time of using silver paste.

It is preferable that, as does the conductive paste, the conductive tape contains carbon or nickel. When the conductive tape contains carbon or nickel, penetration discharge of the semiconductor hardly occurs, and since the plate is formed planary, connection resistance can be lowered to a level similar to the time of using a tape containing silver.

The plate may have a through-hole accessible to the conductive paste, as does the conductive paste. With the plate having such through-hole, the conductive paste enters the through-hole when the plate and common electrode are connected by the conductive paste. This increases mechanical strength, and can further lower the connection resistance. It is preferable that the conductive paste or conductive tape contains carbon or nickel, as does the conductive paste or conductive tape. When the conductive paste or conductive tape contains carbon or nickel, penetration discharge of the semiconductor hardly occurs, and since the plate is formed planarly, connection resistance can be lowered to a level similar to the time of using silver paste.

### EFFECTS OF THE INVENTION

With the radiation detector according to this invention, since the planarly formed conductive plate is connected instead of connecting the lead wire for bias voltage supply directly onto the common electrode for bias voltage application, performance degradation can be avoided. Performance degradation can be avoided without using an insulating seat.

Further, the plate and the common electrode is connected by a conductive paste, which can prevent damage (mechanical damage) to the radiation sensitive semiconductor and can lower connection resistance.

### BRIEF DESCRIPTION OF THE DRAWINGS

FIG. 1 (a) is a schematic plan view of a direct conversion type flat panel X-ray detector (FPD) in Embodiment 1;

FIG. 1 (b) is a section taken on line A-A of FIG. 1 (a);

FIG. 1 (c) is an enlarged view of a portion around a common electrode in FIG. 1 (b);

FIG. 2 is a block diagram showing an equivalent circuit of an active matrix substrate of the flat panel X-ray detector (FPD);

FIG. 3 is a schematic sectional view of the active matrix substrate of the flat panel X-ray detector (FPD);

FIGS. 4 (a) to (c) are schematic sectional views respectively showing combinations of intermediate layers which are carrier selective high resistance semiconductor layers;

FIG. 5 (a) is a schematic plan view of a direct conversion type flat panel X-ray detector (FPD) according to Embodiment 2;

FIG. 5 (b) is an enlarged plan view of a conductive plate with through-holes;

FIG. 5 (c) is an enlarged plan view of the conductive plate when a core wire is connected;

FIG. 5 (d) is an enlarged plan view of the conductive plate when connected by a conductive paste;

FIG. 5 (e) is an enlarged sectional view taken on line A-A of a portion around a common electrode;

FIG. 6 (a) is a schematic plan view of a direct conversion type flat panel X-ray detector (FPD) according to Embodiment 3;

FIG. 6 (b) is a schematic plan view of a direct conversion type flat panel X-ray detector (FPD) which has an extra allowance of space between a radiation detection effective area and an outer circumference of a common electrode;

FIG. 6 (c) is an enlarged view of a portion around the common electrode in FIG. 6 (a);

FIG. 7 (a) is a schematic plan view of a direct conversion type flat panel X-ray detector (FPD) according to Embodiment 4;

FIG. 7 (b) is an enlarged view of a portion around a common electrode in FIG. 7 (a);

FIG. 8 is a schematic sectional view of a conventional X-ray detector;

FIG. 9 is a schematic sectional view of a conventional X-ray detector with a seat different from what is shown in FIG. 8; and

FIG. 10 is a schematic sectional view of a conventional X-ray detector with a seat different from what is shown in FIG. 9.

### DESCRIPTION OF REFERENCES

1 . . . active matrix substrate

2 . . . (radiation sensitive) semiconductor

3 . . . common electrode (for bias voltage application)

4 . . . lead wire (for bias voltage supply)

5a, 5b . . . conductive plates

5c . . . L-shaped metal

5A . . . through-hole

7 . . . conductive paste

8 . . . conductive tape

### Embodiment 1

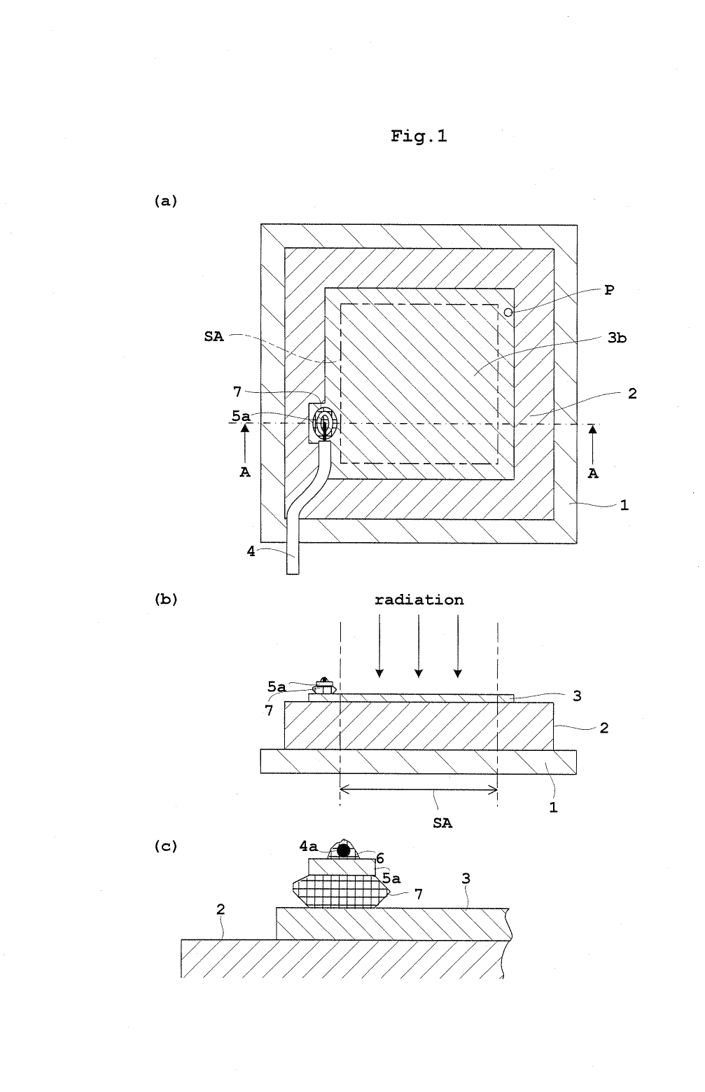

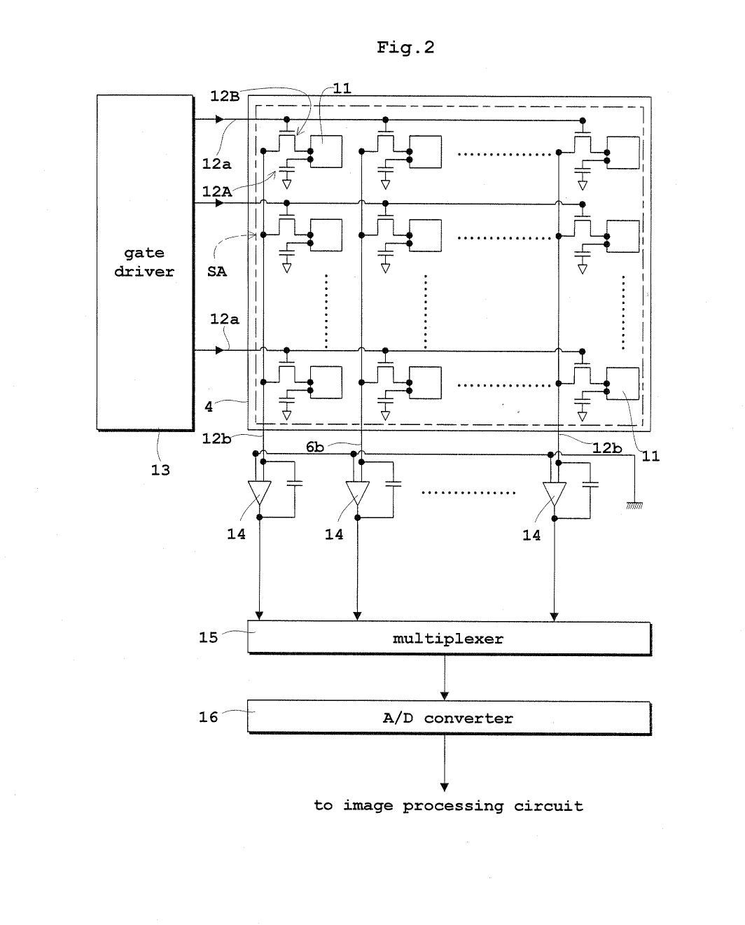

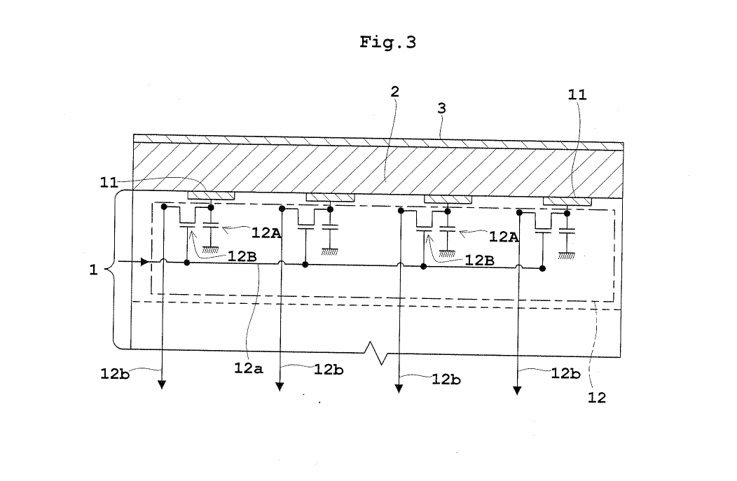

Embodiment 1 of this invention will be described hereinafter with reference to the drawings. FIG. 1 (a) is a schematic plan view of a direct conversion type flat panel X-ray detector (hereinafter abbreviated as “FPD” where appropriate) in Embodiment 1. FIG. 1 (b) is a section taken on line A-A of FIG. 1 (a). FIG. 1 (c) is an enlarged view of a portion around a common electrode in FIG. 1 (b). FIG. 2 is a block diagram showing an equivalent circuit of an active matrix substrate of the flat panel X-ray detector (FPD). FIG. 3 is a schematic sectional view of the active matrix substrate of the flat panel X-ray detector (FPD). In Embodiment 1, including Embodiments 2-4 to follow, the flat panel X-ray detector (FPD) will be described as an example of radiation detector.

As shown in FIGS. 1 (a) and 1 (b), the FPD in Embodiment 1 includes an active matrix substrate 1, a radiation sensitive semiconductor 2 for generating electric charges upon incidence of radiation (X rays in Embodiments 1-4), and a common electrode 3 for bias voltage application. As shown in FIGS. 2 and 3, the active matrix substrate 1 has a plurality of collecting electrodes 11 formed on a radiation incidence surface thereof, and an electric circuit 12 for storing and reading electric charges collected by the respective collecting electrodes 11. The respective collecting electrodes 11 are set in a two-dimensional matrix arrangement inside a radiation detection effective area SA. The radiation sensitive semiconductor 2 corresponds to the radiation sensitive semiconductor in this invention. The common electrode 3 for bias voltage application corresponds to the common electrode for bias voltage application in this invention.

As shown in FIGS. 1 (a) and 1 (b), the semiconductor 2 is laid on the incidence surfaces of the collecting electrodes 11 formed on the active matrix substrate 1, and the common electrode 3 is planarly formed and laid on an incidence surface of the semiconductor 2. Further, as FIGS. 1 (a)-1 (c), a lead wire 4 for bias voltage supply is connected to the incidence surface of the common electrode 3 through the interposition of an oval conductive plate 5a formed, for example, of copper as a planarly formed conductive plate. That is, the lead wire 4 such as a copper wire is connected to the common electrode 3 through the conductive plate 5a interposed therebetween. The conductive plate 5a has surfaces thereof plated with gold (Au) in order to lower resistance further and prevent corrosion. The lead wire 4 for bias voltage supply corresponds to the lead wire for bias voltage supply in this invention. The oval conductive plate 5a corresponds to the conductive plate in this invention.

The forward end of the lead wire 4 is made a core wire 4a with an insulator stripped off a cable and, as shown in FIG. 1 (c), the core wire 4a and conductive plate 5a are connected through a solder 6. On the other hand, the conductive plate 5a and common electrode 3 are connected through a conductive paste 7 interposed therebetween. Therefore, the conductive paste 7 connects the conductive plate 5a and common electrode 3. The conductive paste 7 employed is a nickel acrylic paste which contains nickel. A carbon-based paste having carbon may also be used. In order to provide a stable connection, the conductive paste used has a viscosity of 1000 cps or more, preferably a viscosity of 10000 cps or more. The conductive paste 7 corresponds to the conductive paste in this invention.

As shown in FIGS. 2 and 3, and as described above, the active matrix substrate 1 has the collecting electrodes 11 formed thereon, and the storing and reading electric circuit 12 arranged therein. The storing and reading electric circuit 12 includes capacitors 12A, TFTs (thin film field effect transistors) 12B acting as switching elements, gate lines 12a and data lines 12b. One capacitor 12A and one TFT 12B are correspondingly connected to each of the collecting electrodes 11.

Further, a gate driver 13, charge-to-voltage converting amplifiers 14, a multiplexer 15 and an analog-to-digital converter 16 are arranged around and connected to the storing and reading electric circuit 12 of the active matrix substrate 1. These gate driver 13, charge-to-voltage converting amplifiers 14, multiplexer 15 and analog-to-digital converter 16 are connected via a substrate different from the active matrix substrate 1. Some or all of these gate driver 13, charge-to-voltage converting amplifiers 14, multiplexer 15 and analog-to-digital converter 16 may be built into the active matrix substrate 1.

In time of X-ray detection by the FPD, a bias voltage from a bias supply source (not shown) is applied to the common electrode 3 for bias voltage application via the lead wire 4 for bias voltage supply. The core wire 4a, which is the forward end of the lead wire 4, and the conductive plate 5a are connected through the solder 6, and the conductive plate 5a and common electrode 3 are connected by the conductive paste 7. Thus, the bias voltage is applied from the bias supply source (not shown) to the common electrode 3 through the lead wire 4, solder 6, conductive plate 5a and conductive paste 7. With the bias voltage applied, electric charges are generated in the radiation sensitive semiconductor 2 upon incidence of the radiation (X-rays in Embodiments 1-4). The generated electric charges are first collected by the collecting electrodes 11. The collected electric charges are fetched by the storing and reading electric circuit 12 as radiation detection signals (X-ray detection signals in Embodiments 1-4) from the respective collecting electrodes 11.

Specifically, the electric charges collected by the collecting electrodes 11 are once stored in the capacitors 12A. Then, the gate driver 13 successively applies read signals via the gate lines 12a to the gates of the respective TFTs 12B. With the read signals applied, the TFTs 12B receiving the read signals are switched from off to on-state. As the data lines 12b connected to the sources of the switched TFTs 12B are successively switched on by the multiplexer 15, the electric charges stored in the capacitors 12A are read from the TFTs 12B through the data lines 12b. The electric charges read are amplified by the charge-to-voltage converting amplifiers 14 and transmitted from the multiplexer 15, as radiation detection signals (X-ray detection signals in Embodiments 1-4) from the respective collecting electrodes 11, to the analog-digital converter 16 for conversion analog values to digital values.

Where the FPD is provided for a fluoroscopic apparatus, for example, X-ray detection signals are transmitted to an image processing circuit, disposed at a subsequent stage, for image processing to output a two-dimensional fluoroscopic image or the like. Each of the collecting electrodes 11 in the two-dimensional matrix arrangement corresponds to an electrode (pixel electrode) corresponding to each pixel in the radiographic image (two-dimensional fluoroscopic image here). By fetching the radiation detection signals (X-ray detection signals in Embodiments 1-4), it becomes possible to create a radiographic image (two-dimensional fluoroscopic image here) according to a two-dimensional intensity distribution of the radiation projected to the radiation detection effective area SA. In other words, the FPD in Embodiment 1, and in Embodiments 2-4 to follow, is a two-dimensional array type radiation detector for detecting a two-dimensional intensity distribution of radiation (X-rays in Embodiments 1-4) projected to the radiation detection effective area SA.

Next, each component of the FPD will be described more concretely. A glass substrate, for example, is used for the active matrix substrate 1. The glass substrate for the active matrix substrate 1 is about 0.5 mm to 1.5 mm, for example. The thickness of the semiconductor 2 is typically about 0.5 mm to 1.5 mm, and the area is, for example, about 20 cm to 50 cm long by 20 cm to 50 cm wide.

The radiation sensitive semiconductor 2 preferably is one of an amorphous semiconductor of high purity amorphous selenium (a-Se), selenium or selenium compound doped with an alkali metal such as Na, a halogen such as Cl, As or Te, and a non-selenium base polycrystalline semiconductor such as CdTe, CdZnTe, PbI₂, HgI₂ or TlBr. An amorphous semiconductor of amorphous selenium, selenium or selenium compound doped with an alkali metal, a halogen, As or Te, and a non-selenium base polycrystalline semiconductor, have excellent aptitude for large area and large film thickness. These have a Mohs hardness of 4 or less, and thus are soft and vulnerable to damage. However, the seat 5 can reduce the shock occurring when the lead wire 4 is connected to the common electrode 3, thereby protecting the semiconductor from damage. This facilitates forming the semiconductor 2 with increased area and thickness. In particular, a-Se with a resistivity of 10⁹ Ω or greater, preferably 10¹¹ Ω or greater, has an outstanding aptitude for large area and large film thickness when used for the semiconductor 2.

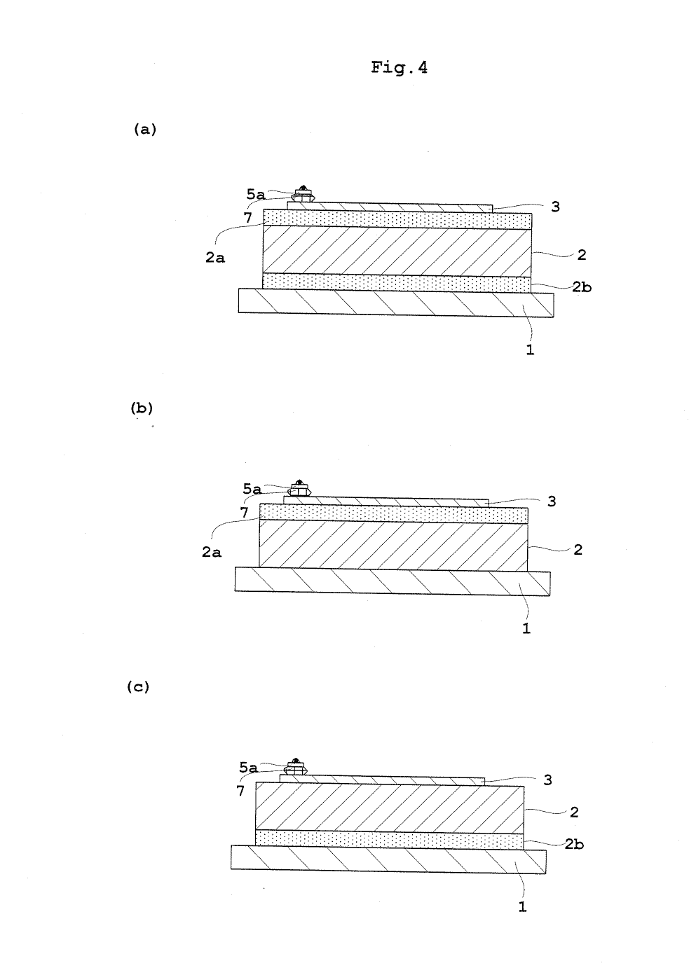

In addition to the sensitive semiconductor 2 described above, the semiconductor 2 may be combined with an intermediate layer which is a carrier selective high-resistance semiconductor layer formed on the incidence surface (upper surface in FIG. 1 (b)) or the other surface (lower surface in FIG. 1 (b)) or both surfaces. As shown in FIG. 4 (a), an intermediate layer 2a may be formed between the semiconductor 2 and the common electrode 3, and an intermediate layer 2b may be formed between the semiconductor 2 and the collecting electrodes 11 (see FIG. 3). As shown in FIG. 4 (b), the intermediate layer 2a may be formed only between the semiconductor 2 and the common electrode 3. As shown in FIG. 4 (c), the intermediate layer 2b may be formed only between the semiconductor 2 and the collecting electrodes 11 (see FIG. 3).

With the carrier selective intermediate layers 2a and 2b disposed as above, dark current can be reduced. The carrier selectivity here refers to a property of being remarkably different in contribution to the charge transfer action between electrons and holes which are charge transfer media (carriers) in a semiconductor.

The semiconductor 2 and the carrier selective intermediate layers 2a and 2b may be combined in the following modes. Where a positive bias voltage is applied to the common electrode 3, the intermediate layer 2a is formed of a material having a large contribution of electrons. This prevents an infiltration of holes from the common electrode 3, thereby reducing dark current. The intermediate layer 2b is formed of a material having a large contribution of holes. This prevents an infiltration of electrons from the collecting electrodes 11, thereby reducing dark current.

Conversely, where a negative bias voltage is applied to the common electrode 3, the intermediate layer 2a is formed of a material having a large contribution of holes. This prevents an infiltration of electrons from the common electrode 3, thereby reducing dark current. The intermediate layer 2b is formed of a material having a large contribution of electrons. This prevents an infiltration of holes from the collecting electrodes 11, thereby reducing dark current.

A preferred thickness of the carrier selective intermediate layers 2a and 2b normally is in a range of 0.1 μm to 10 μm. A thickness of the intermediate layers 2a and 2b less than 0.1 μm tends to be incapable of suppressing dark current sufficiently. Conversely, a thickness exceeding 10 μm tends to obstruct radiation detection (e.g. tends to lower sensitivity).

Semiconductors usable for the carrier selective intermediate layers 2a and 2b and having an excellent aptitude for large area include polycrystalline semiconductors such as Sb₂S₃, ZnTe, CeO₂, CdS, ZnSe or ZnS, or amorphous semiconductors of selenium or selenium compound doped with an alkali metal such as Na, a halogen such as Cl, As or Te. These semiconductors are thin and vulnerable to scratch. However, the seat 5 can reduce the shock occurring when the lead wire 4 is connected to the common electrode 3, thereby protecting the intermediate layers from damage. This provides the carrier selective intermediate layers 2a and 2b with an excellent aptitude for large area.

Among the semiconductors usable for the intermediate layers 2a and 2b, those having a large contribution of electrons include n-type semiconductors including polycrystalline semiconductors such as CeO₂, CdS, CdSe, ZnSe or ZnS, and amorphous materials such as amorphous selenium doped with an alkali metal, As or Te to reduce the contribution of holes.

Those having a large contribution of holes may be p-type semiconductors including polycrystalline semiconductors such as ZnTe, and amorphous materials such as amorphous selenium doped with a halogen to reduce the contribution of electrons.

Further, Sb₂S₃, CdTe, CdZnTe, PbI₂, HgI₂, TlBr, non-doped amorphous selenium or selenium compounds include the type having a large contribution of electrons and the type having a large contribution of holes. Either type may be selected for use as long as film forming conditions are adjusted.

The conductive plate 5a is plated with gold as noted hereinbefore. The conductive plate 5a has a planar shape and is oval (shaped elliptical). The area of the conductive plate 5a is, for example, about 10 mm to 15 mm long by 5 mm to 10 mm wide, and its thickness is about 1 mm.

Next, a method of connecting the common electrode 3 and adjacent components of the FPD will be described. As the semiconductor 2, a thick film of amorphous selenium is used here, which is 1.0 mm thick and has an area 510 mm by 510 mm. As shown in FIG. 4 (a), intermediate layers 2a and 2b formed of Sb₂S₃ are used on the upper and lower sides of the thick film of amorphous selenium. As the conductive plate 5a, what is used is a conductive plate 5a which is 1 mm thick and has an area 12 mm long by 7 mm wide, and which is plated with gold. The common electrode 3 used is formed of gold (Au). The surface of the conductive plate 5a opposed to the common electrode 3 is made as tabular as possible, or planar with slight swelling, in order not to damage the gold electrode forming the common electrode 3.

Next, a high-voltage cable of lead wire 4 is cut to a predetermined length, and the insulator at the forward end is stripped off to leave only the core wire 4a. The core wire 4a and the conductive plate 5a plated with gold as noted above are soldered, whereby the core wire 4a and conductive plate 5a are connected through the solder 6.

The FPD having undergone a vapor deposition of the amorphous selenium and gold electrode is made available. A nickel acrylic paste is applied to the back surface (i.e. the surface facing the gold electrode) of the conductive plate 5a, which is installed in a predetermined position of the gold electrode, whereby the conductive plate 5a and the common electrode 3 formed of the gold electrode are connected by the conductive paste 7. After waiting for the conductive paste 7 to become dry and solid, the operation proceeds to the next step. At this time, the nickel acrylic paste is applied in such a quantity that the conductive plate 5a does not directly touch the gold electrode when pressed on the gold electrode surface. Application in a small quantity will result in the conductive plate 5a directly touching the gold electrode surface, whereby the conductive plate 5a may damage the electrode surface. Conversely, application in a large quantity will increase a protrusion. As described above, it is possible to connect the lead wire 4 to the common electrode 3 without forming a seat of resin before the vapor deposition formation of the gold electrode, and thus without contaminating the vapor deposition apparatus.

After connecting the high-voltage cable 700 mm in length after the nickel acrylic paste dried and solidified, measurement was carried out with a digital tester between the core wire 4a located at the forward end and a resistance measurement point P shown in FIG. 1 (a). It has been confirmed that the resistance was 2.7Ω. From the value measured on a condition of silver paste on a conventional seat formed of resin being 2 to 3Ω, it is thought that the connection resistance value by the connecting method according to this Embodiment 1 is equivalent to the conventional method of installing the seat.

The plating of the conductive plate 5a is not limited to gold, but plating may be done with other metal. When the conductive plate 5a is formed of metal such as aluminum, plating is not absolutely necessary. The connection between the core wire 4a and conductive plate 5a is made by soldering which is the most common and provides a reliable connection. Soldering has an advantage of allowing selection from many cables made available beforehand. Of course, soldering is not limitative, but connection by conductive paste or connection by welding may be made, or part of a conductive plate formed planarly, represented by the conductive plate 5a, may be thinned and a cable may be connected to that portion by fastening them together.

According to the flat panel X-ray detector (FPD) in this Embodiment 1 described above, the common electrode 3 for bias voltage application and the lead wire 4 for bias voltage supply are connected through the planarly formed conductive plate (conductive plate 5a in this Embodiment 1) interposed therebetween. Since the planarly formed plate (conductive plate 5a) is connected instead of connecting the lead wire 4 directly onto the common electrode 3, it can prevent damage to the radiation sensitive semiconductor 2 and avoid performance degradation. Since the plate (conductive plate 5a) is formed planarly, even if a conductive paste with high resistance is used, connection resistance can be lowered to be comparable to the use of silver paste. That is, the range of selection of the conductive paste is broadened. Also, connection can be made without using an insulating seat and performance degradation can be avoided. As a result, performance degradation can be avoided, without using an insulating seat.

In this Embodiment 1, the plate (conductive plate 5a in this Embodiment 1) and common electrode 3 are connected by the conductive paste 7. Preferably, the conductive paste 7 contains carbon or nickel. A nickel acrylic paste is employed in this Embodiment 1. When the conductive paste 7 is silver paste, although connection resistance is low, diffusion to the semiconductor 2 represented by amorphous selenium is large, which will lower even the resistance of the semiconductor 2, causing penetration discharge of the semiconductor 2 by application of the bias voltage. When the conductive paste 7 is a carbon-based paste or nickel-based paste containing carbon or nickel (nickel acrylic paste in this Embodiment 1), diffusion to the semiconductor 2 is small compared with the silver paste, and hardly causes penetration discharge of the semiconductor 2. When the conductive paste 7 is a carbon-based paste or nickel-based paste containing carbon or nickel, although connection resistance becomes high, since the plate (conductive plate 5a) is formed planarly, connection resistance can be lowered to a level similar to the time of using silver paste.

### Embodiment 2

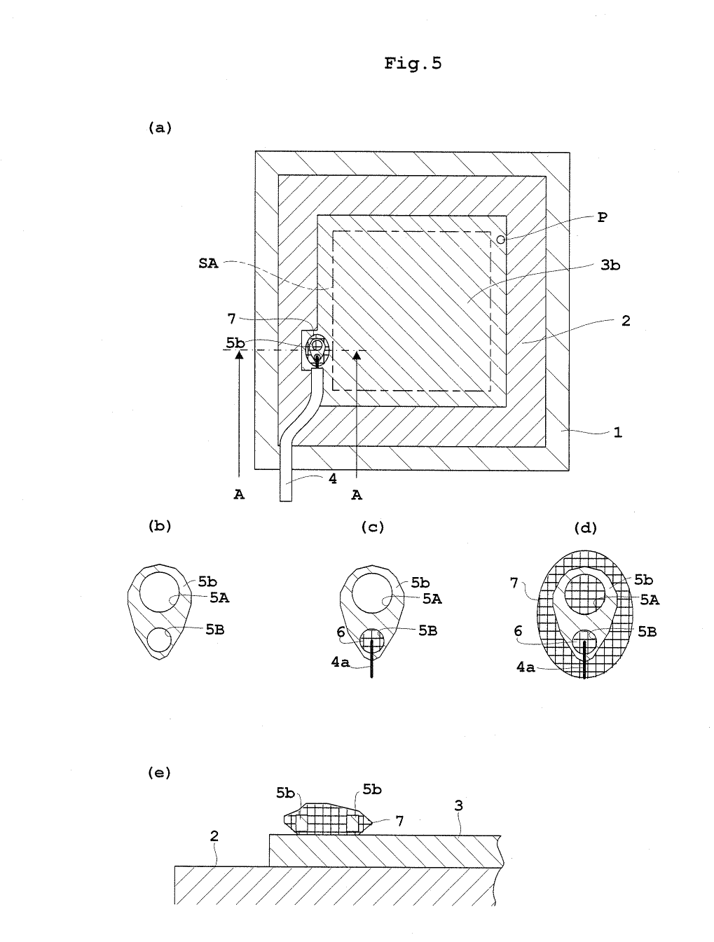

Next, Embodiment 2 of this invention will be described with reference to the drawings. FIG. 5 (a) is a schematic plan view of a direct conversion type flat panel X-ray detector (FPD) according to Embodiment 2. FIG. 5 (b) is an enlarged plan view of a conductive plate with through-holes. FIG. 5 (c) is an enlarged plan view of the conductive plate when a core wire is connected. FIG. 5 (d) is an enlarged plan view of the conductive plate when a conductive paste is connected. FIG. 5 (e) is an enlarged sectional view taken on line A-A of a portion around a common electrode. Parts in common with foregoing Embodiment 1 are designated by the same reference numbers, and will not be described or shown in the drawings again.

The FPD according to this Embodiment 2, as shown in FIGS. 5 (a)-5 (d), employs a conductive plate 5b with two through-holes 5A and 5B as the conductive plate formed planarly. This conductive plate 5b is also called an “egg lug”, and what is commercially available can be used. Usually, an “egg lug” is plated with nickel, and can be used as it is. Of the two through-holes 5A and 5B, the through-hole 5A is a hole for receiving the conductive paste 7 when the conductive plate 5b and common electrode 3 are connected by the conductive paste 7. The through-hole 5B is a hole for connecting the core wire 4a with the insulator stripped off the cable and the conductive plate 5b through a solder 6. The through-hole 5A has a larger bore size than the through-hole 5B. The conductive plate 5b corresponds to the conductive plate in this invention. The through-hole 5A corresponds to the through-hole in this invention.

The conductive paste 7 employed contains nickel, as does the nickel acrylic paste, as in Embodiment 1. Of course, a carbon-based paste having carbon may be used. In order to provide a stable connection, the conductive paste used has a viscosity of 1000 cps or more, preferably a viscosity of 10000 cps or more.

Next, a method of connecting the common electrode 3 and adjacent components of the FPD will be described. As in Embodiment 1, as shown in FIG. 4 (a), intermediate layers 2a and 2b formed of Sb₂S₃ are used on the upper and lower sides of the thick film of amorphous selenium. The common electrode 3 used is formed of gold (Au).

A high-voltage cable of lead wire 4 is cut to a predetermined length, and the insulator at the forward end is stripped off to leave only the core wire 4a. The core wire 4a and the location of through-hole 5B of the conductive plate 5b plated with gold as noted above are soldered, whereby the core wire 4a and conductive plate 5b are connected through the solder 6 as shown in FIG. 5 (c).

A nickel acrylic paste is applied to the front and back surfaces in the location of through-hole 5B of the conductive plate 5b, which is installed in a predetermined position of the gold electrode, or the nickel acrylic paste is applied to the predetermined position of the gold electrode and the conductive plate 5b is installed on the nickel acrylic paste, whereby the conductive plate 5b and the common electrode 3 formed of the gold electrode are connected by the conductive paste 7. At this time, the conductive paste 7 consisting of the nickel acrylic paste enters the through-hole 5A. The conductive paste 7 consisting of the nickel acrylic paste may be caused to enter the through-hole 5A by applying the nickel acrylic paste to the back surface (i.e. the surface facing the gold electrode) including also the location of through-hole 5A of the conductive plate 5b, installing it in the predetermined position of the gold electrode, and thereafter applying the nickel acrylic paste also to the front surface centering around the location of through-hole 5A.

After waiting for the conductive paste 7 to become dry and solid, the operation proceeds to the next step. As in Embodiment 1, the nickel acrylic paste is applied in such a quantity that the conductive plate 5b does not directly touch the gold electrode when pressed on the gold electrode surface. However, the quantity of application is larger in this Embodiment 2 than in Embodiment 1 by the part entering the through-hole 5A of the conductive paste 7 consisting of the nickel acrylic paste.

Usually the conductive plate 5b called “egg lug” is plated with nickel, but may be plated with other metal. Plating is not absolutely necessary. The connection between the core wire 4a and conductive plate 5a is not limited to soldering, but connection by conductive paste or connection by welding may be made, or part of a conductive plate formed planarly, represented by the conductive plate 5b, may be thinned and a cable may be connected to that portion by fastening them together.

According to the flat panel X-ray detector (FPD) in this Embodiment 2 described above, as in Embodiment 1 described hereinbefore, the common electrode 3 for bias voltage application and the lead wire 4 for bias voltage supply are connected through the planarly formed conductive plate (conductive plate 5b in this Embodiment 2) interposed therebetween. Since the planarly formed plate (conductive plate 5b) is connected instead of connecting the lead wire 4 directly onto the common electrode 3, it can prevent damage to the radiation sensitive semiconductor 2 and avoid performance degradation. Performance degradation can be avoided, without using an insulating seat.

In this Embodiment 2, as in Embodiment 1 described hereinbefore, the plate (conductive plate 5b in this Embodiment 2) and common electrode 3 are connected by the conductive paste 7. Preferably, the conductive paste 7 contains carbon or nickel. A nickel acrylic paste is employed also in this Embodiment 2. When the conductive paste 7 is a carbon-based paste or nickel-based paste containing carbon or nickel (nickel acrylic paste in this Embodiment 2), diffusion to the semiconductor 2 is small compared with the silver paste, and hardly causes penetration discharge of the semiconductor 2. When the conductive paste 7 is a carbon-based paste or nickel-based paste containing carbon or nickel, although connection resistance becomes high, since the plate (conductive plate 5b) is formed planarly, connection resistance can be lowered to a level similar to the time of using silver paste.

In this Embodiment 2, the plate (conductive plate 5b in this Embodiment 2) has the through-hole 5A accessible to the conductive paste 7. With the plate (conductive plate 5b) having such through-hole 5A, the conductive paste 7 enters the through-hole 5A when the plate (conductive plate 5b) and common electrode 3 are connected by the conductive paste 7. This increases mechanical strength, and can further lower the connection resistance.

### Embodiment 3

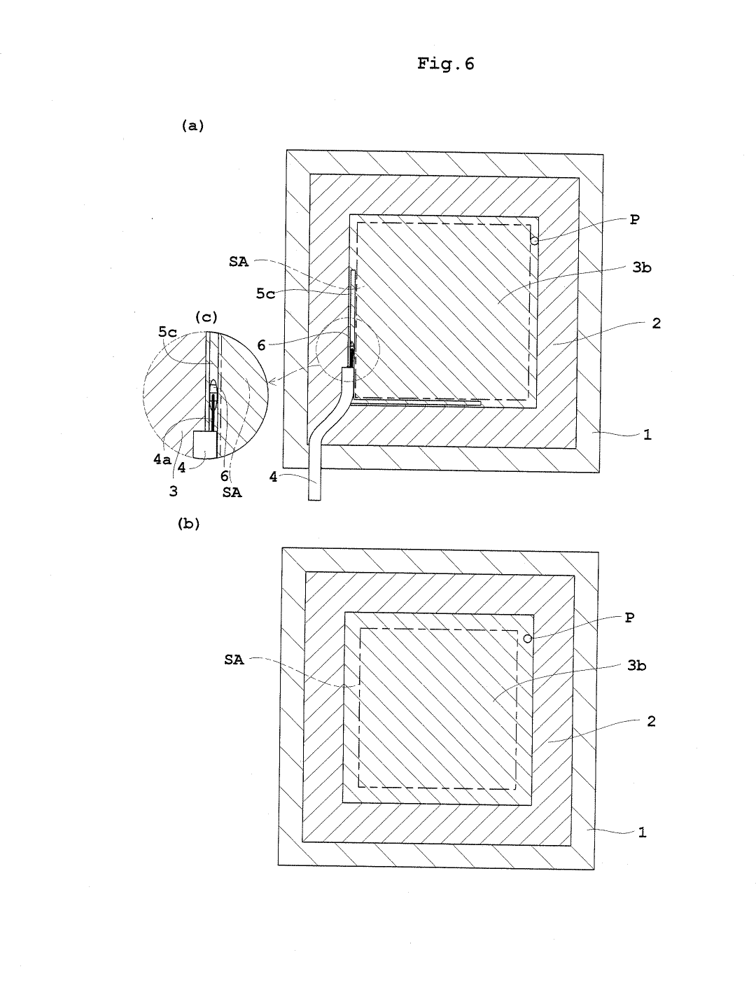

Next, Embodiment 3 of this invention will be described with reference to the drawings. FIG. 6 (a) is a schematic plan view of a direct conversion type flat panel X-ray detector (FPD) according to Embodiment 3. FIG. 6 (b) is a schematic plan view of a direct conversion type flat panel X-ray detector (FPD) which has an extra allowance of space between a radiation detection effective area and an outer circumference of a common electrode. FIG. 6 (c) is an enlarged view of a portion around the common electrode in FIG. 6 (a). Parts in common with foregoing Embodiments 1 and 2 are designated by the same reference numbers, and will not be described or shown in the drawings again.

The FPDs according to foregoing Embodiments 1 and 2 employ the conductive plate as the conductive plate formed planarly as shown in FIGS. 1 and 5. The FPD according to this Embodiment 3, as shown in FIG. 6, employs an L-shaped metal 5c as the conductive plate formed planarly.

When there is an extra allowance of space between the radiation detection effective area SA and the outer circumference of the common electrode 3 as shown in FIG. 6 (b), as in FIG. 1 (a) of foregoing Embodiment 1 and FIG. 5 (a) of foregoing Embodiment 2, the conductive plate 5a of Embodiment 1 or the conductive plate 5b of Embodiment 2 installed does not overhang the radiation detection effective area SA. However, when there is no extra allowance of space between the radiation detection effective area SA and the outer circumference of the common electrode 3 as shown in FIG. 6 (a), the conductive plate 5a of Embodiment 1 or the conductive plate 5b of Embodiment 2 installed could overhang the radiation detection effective area SA. The radiation detection effective area SA is also an area where the collecting electrodes 11 (see FIGS. 2 and 3) corresponding to the pixel electrodes can be arranged. Therefore, the radiation detection effective area SA is also called the “pixel area”.

So, as shown in FIG. 6 (a), when there is no extra allowance of space between the radiation detection effective area SA and the outer circumference of the common electrode 3, a plate of smaller size or narrower width than the conductive plate 5a of Embodiment 1 or the conductive plate 5b of Embodiment 2 is substituted. At this time, the length direction is made as long as possible in order to increase the area of contact with the common electrode 3 as a whole to secure stable fixation. Therefore, the L-shaped metal 5c formed in a shape of character L is installed between the radiation detection effective area SA and the outer circumference of the common electrode 3, along a corner of the common electrode 3. The L-shaped metal 5c corresponds to the conductive plate in this invention.

Next, a method of connecting the common electrode 3 and adjacent components of the FPD will be described. As in Embodiments 1 and 2, as shown in FIG. 4 (a), intermediate layers 2a and 2b formed of Sb₂S₃ are used on the upper and lower sides of the thick film of amorphous selenium. The common electrode 3 used is formed of gold (Au).

A high-voltage cable of lead wire 4 is cut to a predetermined length, and the insulator at the forward end is stripped off to leave only the core wire 4a. The core wire 4a and L-shaped metal 5c are soldered, whereby the core wire 4a and L-shaped metal 5c are connected through the solder 6 as shown in FIG. 6 (c).

A nickel acrylic paste is applied to the back surface (i.e. the surface facing the gold electrode) of the L-shaped metal 5c, which is installed in a predetermined position of the gold electrode, whereby the L-shaped metal 5c and the common electrode 3 formed of the gold electrode are connected by the conductive paste 7. As in Embodiment 4 described hereinafter, a double-sided adhesive or single-sided adhesive conductive tape may be used as the L-shaped metal 5c. In this case, it is not absolutely necessary to use the conductive paste, but the L-shaped metal 5c formed of the conductive tape and the common electrode 3 formed of the gold electrode may be connected by the conductive paste.

As are the conductive plate 5a of Embodiment 1 and the conductive plate 5b of Embodiment 2, the L-shaped metal 5c may be plated with metal (e.g. plated with gold), but plating is not absolutely necessary. The connection between the core wire 4a and L-shaped metal 5c is not limited to soldering, but connection by conductive paste or connection by welding may be made.

According to the flat panel X-ray detector (FPD) in this Embodiment 3 described above, as in Embodiments 1 and 2 described hereinbefore, the common electrode 3 for bias voltage application and the lead wire 4 for bias voltage supply are connected through the planarly formed conductive plate (L-shaped metal 5c in this Embodiment 3) interposed therebetween. Since the planarly formed plate (L-shaped metal 5c) is connected instead of connecting the lead wire 4 directly onto the common electrode 3, it can prevent damage to the radiation sensitive semiconductor 2 and avoid performance degradation. Performance degradation can be avoided, without using an insulating seat.

### Embodiment 4

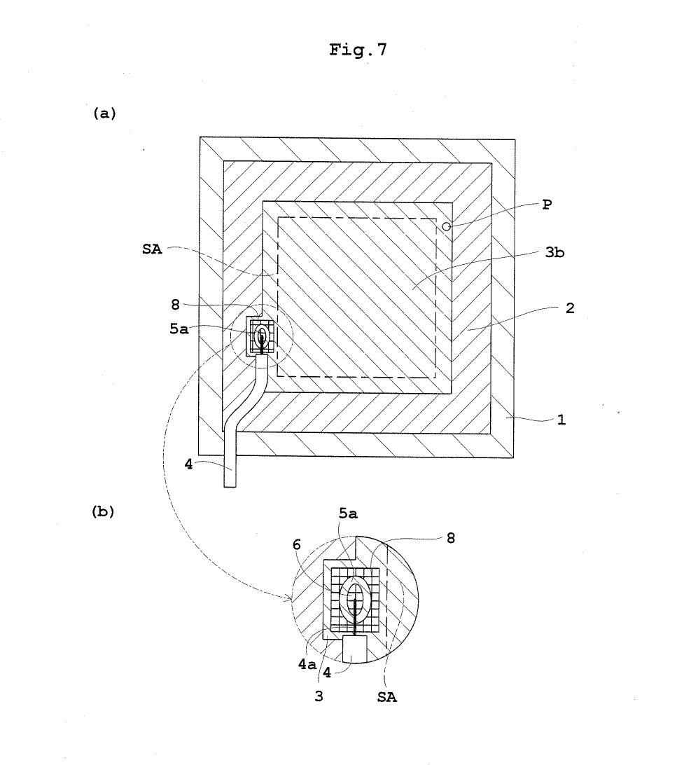

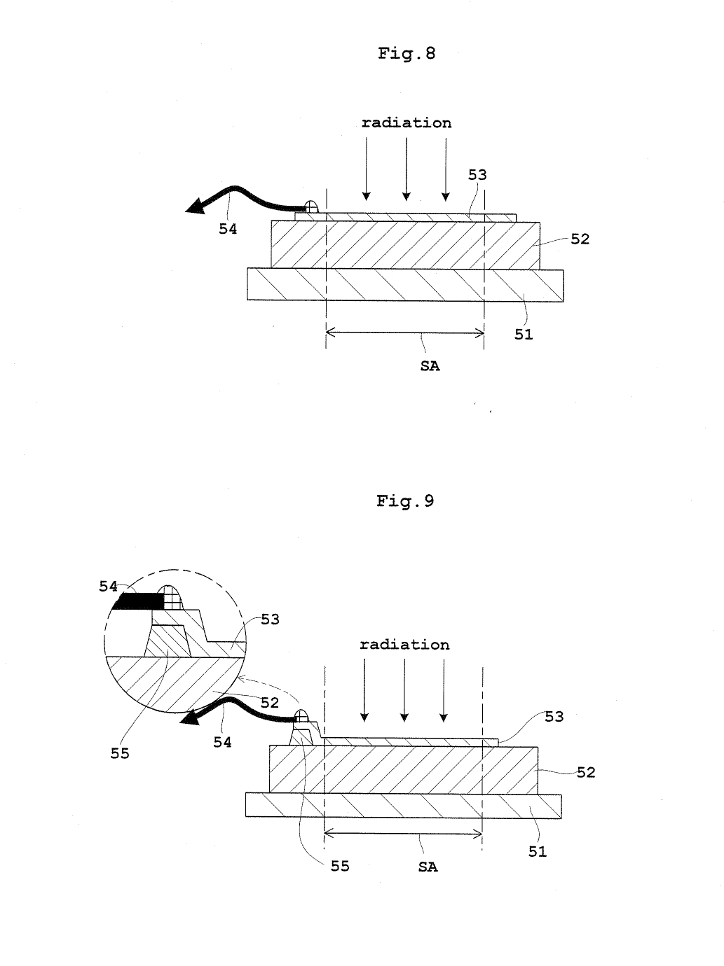

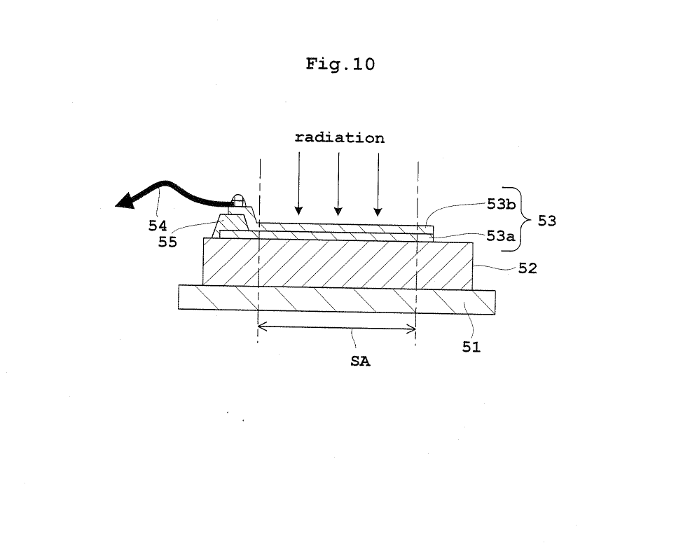

Next, Embodiment 4 of this invention will be described with reference to the drawings. FIG. 7 (a) is a schematic plan view of a direct conversion type flat panel X-ray detector (FPD) according to Embodiment 4. FIG. 7 (b) is an enlarged view of a portion around the common electrode in FIG. 7 (a). Parts in common with foregoing Embodiments 1-3 are designated by the same reference numbers, and will not be described or shown in the drawings again.

The FPDs according to foregoing Embodiments 1 and 2 employ the conductive plate as the conductive plate formed planarly as shown in FIGS. 1 and 5. The FPD according to this Embodiment 4, as shown in FIG. 7, uses a conductive tape 8 for connecting the common electrode 3 and the conductive plate formed planarly. This Embodiment 4, as does Embodiment 1, employs the conductive plate 5a as the conductive plate formed planarly. Of course, the conductive plate 5b which is an “egg lug” with through-holes may be employed as the conductive plate formed planarly as in Embodiment 2. The conductive tape 8 corresponds to the conductive tape in this invention.

The conductive tape 8 employed contains carbon or nickel. When a conductive paste is not used on the conductive tape 8 in combination, a double-sided adhesive conductive tape is used to connect the conductive plate 5a, which is connected to the lead wire 4, and the common electrode 3. When a conductive paste is used on the conductive tape 8 in combination, a single-sided adhesive conductive tape may be used, or a double-sided adhesive conductive tape may be used. In order to provide a stable connection, the conductive tape used has a viscosity of 1000 cps or more, preferably a viscosity of 10000 cps or more.

Next, a method of connecting the common electrode 3 and adjacent components of the FPD will be described. As in Embodiments 1-3, as shown in FIG. 4 (a), intermediate layers 2a and 2b formed of Sb₂S₃ are used on the upper and lower sides of the thick film of amorphous selenium. The common electrode 3 used is formed of gold (Au).

A high-voltage cable of lead wire 4 is cut to a predetermined length, and the insulator at the forward end is stripped off to leave only the core wire 4a. The core wire 4a and the conductive plate 5a are soldered, whereby the core wire 4a and conductive plate 5a are connected through the solder 6 as shown in FIG. 7 (b).

On the other hand, the conductive tape 8 is applied to a predetermined position of the gold electrode, and the core wire 4a and conductive plate 5a connected through the solder 6 are installed on the conductive tape 8 applied, whereby the conductive tape 8 connects the conductive plate 5a and the common electrode 3 formed of the gold electrode. In the case of the conductive tape 8, it is not necessary to apply in a proper quantity, like the conductive paste, to the conductive plate 5a, but a tape of required length may only be cut and applied. Like an adhesive such as the conductive paste, time taken until it solidifies and dries is substantially zero. That is, since the operation can immediately proceed to the next step, working hours are shortened also.

When, as in Embodiment 2, the conductive plate 5b with through-holes is employed as the conductive plate formed planarly, as shown in FIG. 5, the core wire 4a and the location of the through-hole 5B of the conductive plate 5b are soldered, whereby the core wire 4a and conductive plate 5b are connected through the solder 6. And the conductive paste 7 is applied to the location of the through-hole 5A, and the core wire 4a and conductive plate 5b connected through the solder 6 are installed on the conductive tape 8 applied to the common electrode 3, whereby the conductive tape 8 and the conductive paste 7 formed thereon connect the conductive plate 5b and the common electrode 3 formed of the gold electrode. In this way, the conductive tape 8 and the conductive paste 7 formed thereon connect the plate (conductive plate 5b here) and the common electrode 3.

In addition, the core wire 4a and conductive plate 5a are connected through the solder 6 by soldering the core wire 4a and conductive plate 5a, the conductive paste 7 is applied to the back surface of the conductive plate 5a, and the core wire 4a and conductive plate 5a connected through the solder 6 are installed on the conductive tape 8 applied to the common electrode 3, whereby the conductive tape 8 and the conductive paste 7 formed thereon connect the conductive plate 5a and the common electrode 3 formed of the gold electrode. In this way, the conductive tape 8 and the conductive paste 7 formed thereon connect the plate (conductive plate 5a here) and the common electrode 3.

According to the flat panel X-ray detector (FPD) in this Embodiment 4 described above, as in Embodiments 1-3 described hereinbefore, the common electrode 3 for bias voltage application and the lead wire 4 for bias voltage supply are connected through the planarly formed conductive plate (conductive plate 5a in this Embodiment 4) interposed therebetween. Since the planarly formed plate (conductive plate 5a) is connected instead of connecting the lead wire 4 directly onto the common electrode 3, it can prevent damage to the radiation sensitive semiconductor 2 and avoid performance degradation. Performance degradation can be avoided, without using an insulating seat.

In this Embodiment 4, as distinct from Embodiments 1 and 2, the plate (conductive plate 5a in this Embodiment 4) and common electrode 3 are connected by the conductive tape 8. Preferably, the conductive tape 8 contains carbon or nickel. When the conductive tape 8 contains carbon or nickel, penetration discharge of the semiconductor 2 hardly occurs, and since the plate (conductive plate 5a) is formed planary, connection resistance can be lowered to a level similar to the time of using a tape containing silver.

When connecting the plate (conductive plate 5a, 5b) and common electrode 3 by the conductive tape 8 and the conductive paste 7 formed thereon, the following function and effect are provided. Although resistivity may become high with the conductive tape 8 compared with the conductive paste 7, when connection is made by the conductive tape 8 and the conductive paste 7 formed thereon, resistance can be lowered since the conductive paste 7 is formed on the conductive tape 8 to be used in combination.

When the plate (conductive plate 5a, 5b) and common electrode 3 are connected by the conductive tape 8 and the conductive paste 7 formed thereon, as noted hereinbefore, the plate (conductive plate 5b here) may have the through-hole 5A accessible to the conductive paste 7. With the plate (conductive plate 5b) having such through-hole 5A, the conductive paste 7 enters the through-hole 5A when the plate (conductive plate 5b) and common electrode 3 are connected by the conductive paste 7. This increases mechanical strength, and can further lower the connection resistance.

### Experimental Results

Results of measurement made of various resistances in an FPD with the common electrode 3 formed by vapor deposition of gold about 60 mm long by about 60 mm wide on the semiconductor 2 formed of amorphous selenium are shown. The resistances have been measured using a nickel-plated conductive plate 5a about 15 mm long by about 10 mm wide.

(A) is a case of connection by a small quantity of silver-based conductive paste, (B) is a case of connection by a nickel-based double-sided adhesive conductive tape, and (C) is a case of connection by a nickel-based conductive paste. In the case (A), it was intended to apply the silver-based conductive paste to the surface of a silver-based double-sided adhesive conductive tape, to be compared with other cases, but the conductive paste protruded from the conductive tape. Since the resistance in this portion must be small, the connection was made by a small quantity of silver-based conductive paste as substitute. Normally, with only the silver-based conductive paste, silver would readily diffuse to the thick film of amorphous selenium when a bias voltage of high voltage was applied. Therefore, (A) is not used on its own.

In (A)-(C), after attaching the silver-based double-sided adhesive conductive tape to the semiconductor formed of the gold electrode, the silver-based conductive paste is applied to the entire surface, to hold down each resistance to about 0.2Ω. Since the connection between the conductive plate 5a and the lead wire is made by soldering, a difference in connection resistance value is substantially at a negligible level. The cables of the lead wires are about 30 cm, and measurement is taken between the common electrode and the forward end of each cable. As a result, measurement results obtained are 1.8Ω for (A), 4.3Ω for (B), and 1.8Ω for (C).

It has been confirmed from the above that, substantially the same result is obtained for (C) in which the connection is made by the nickel-based conductive paste, as the result for (A) using the silver-based conductive paste. As is clear from the result of (B) in which the connection is made by the nickel-based double-sided adhesive conductive tape, the resistance is higher than at the time of using the conductive pastes in (A) and (C). Although use is possible in this case also, it is possible to lower the resistance by combined use of the conductive paste.

This invention is not limited to the above embodiments, but may be modified as follows:

(1) The radiation detectors, as typified by flat panel X-ray detectors, described in the above embodiments are the two-dimensional array type. The radiation detector according to this invention may be the one-dimensional array type having collecting electrodes formed in a one-dimensional matrix array, or the non-array type having a single electrode for fetching radiation detection signals.

(2) In the above embodiments, the radiation detectors are described taking X-ray detectors for example. However, this invention may be applied to radiation detectors (e.g. gamma ray detectors) for detecting radiation other than X-rays (e.g. gamma rays).

(3) In each of the above embodiments, the common electrode 3 is formed inwardly of the semiconductor 2 in order to prevent creeping discharge. When creeping discharge is left out of consideration, the edges of the common electrode 3 and the semiconductor 2 may be placed flush, or the common electrode 3 may be formed outwardly of the semiconductor 2.

1. A radiation detector for detecting radiation, comprising:
a radiation sensitive semiconductor for generating electric charges upon incidence of the radiation;
a common electrode for bias voltage application formed planarly on an incidence surface of the semiconductor;
a lead wire for bias voltage supply; and
a conductive plate formed planarly;
wherein the common electrode and the lead wire are connected through the plate interposed therebetween and the plate and the common electrode are connected by a conductive paste.

2. (canceled)

3. The radiation detector according to claim 1, wherein the plate has a through-hole accessible to the conductive paste.

4. The radiation detector according to claim 1, wherein the conductive paste contains carbon or nickel.

5. The radiation detector according to claim 1, wherein the plate and the common electrode are connected by a conductive tape.

6. The radiation detector according to claim 5, wherein the conductive tape contains carbon or nickel.

7. The radiation detector according to claim 1, wherein the plate and the common electrode are connected by a conductive tape and a conductive paste formed thereon.

8. The radiation detector according to claim 7, wherein the plate has a through-hole accessible to the conductive paste.

9. The radiation detector according to claim 7, wherein the conductive paste or the conductive tape contains carbon or nickel.
